(19) United States
(12) Patent Application Publication
(10) Pub. No.: US 2002/0028545 A1
(43) Pub. Date: Mar. 7, 2002

(54) HIGHLY RESISTIVE STATIC RANDOM ACCESS MEMORY AND METHOD OF FABRICATING THE SAME

(76) Inventor: NORIYUKI OTA, TOKYO (JP)

Correspondence Address: SUGHRUE MION ZINN MACPEAK & SEAS, 2100 PENNSYLVANIA AVENUE N W, WASHINGTON, DC, 20037

(21) Appl. No.: 09/280,703

(22) Filed: Mar. 30, 1999

(30) Foreign Application Priority Data
Mar. 30, 1998 (JP) 10-083182

(51) Int. Cl. H01L 21/338

(52) U.S. Cl. 438/184; 438/230; 438/303

(57) ABSTRACT

The present invention provides a semiconductor diffusion region structure of a first conductivity type in an upper region of a semiconductor substrate of a second conductivity type, wherein the semiconductor diffusion region structure comprises: a main portion, at least a part of which is electrically connected to an electrically conductive film structure; and an extending portion which underlies a gate insulating film underlying a gate electrode layer which is also electrically connected to the electrically conductive film structure, so that an adjacent potion of the semiconductor substrate to an edge of the extending portion of the semiconductor diffusion region structure is distanced from the electrically conductive film structure whereby the semiconductor diffusion region structure is electrically isolated from the semiconductor substrate.

### BACKGROUND OF THE INVENTION

The present invention relates to a highly resistive load static random access memory device having an improved connective structure between a gate electrode and a diffusion layer and a method of forming the same.

FIG. 1 is a circuit diagram illustrative of a conventional highly resistive static random access memory. The conventional highly resistive static random access memory has a pair of first and second driver MOS field effect transistors Tr1 and Tr2, and a pair of first and second transfer MOS field effect transistors Tr3 and Tr4 as well as a pair of first and second high resistances R1 and R2. FIG. 2 is a fragmentary plane view illustrative of the conventional highly resistive static random access memory of FIG. 1. The conventional highly resistive static random access memory has an impurity diffusion region SD, gates G1 and G2 of the first and second driver MOS field effect transistors Tr1 and Tr2 word lines WL of the first and second transfer MOS field effect transistors, contacts RCT of the high resistances R1 and R2 and the impurity diffusion layers SD, a first power source contact VCC and a second power source contact VSS.

The conventional highly resistive static random access memory has a circuit configuration that the first and second transfer MOS field effect transistors are complementary connected to gates of the second and first driver MOS field effect transistors Tr2 and Tr1 through connective regions Q1 and Q2. Those connective regions Q1 and Q2 are unitary formed. FIG. 3 is a fragmentary cross sectional elevation view illustrative of the conventional highly resistive static random access memory taken along an A-A line of FIG. 2. Field oxide films 2 are formed on a main face of a semiconductor substrate 1 to define an active region of the semiconductor substrate 1. A diffusion layer 5 is selectively formed on the active region of the semiconductor substrate 1. The diffusion layer 5 serves as a source or drain region of the first transfer MOS field effect transistor Tr3 and the first driver MOS field effect transistor Tr1. The diffusion layer 5 comprises a heavily doped n+-type diffusion region 5a and a lightly doped n−-type diffusion region 5b. A gate electrode 4 is formed on a gate oxide film over a channel region and the field oxide film 2. A conductive film 6 of titanium is further formed which extends on the diffusion layer 5 and on the gate electrode 4. A first inter-layer insulator 7 is formed over the titanium film 6. A contact hole 8 is formed in the first inter-layer insulator 7 in the connective region Q1 through which the first transfer MOS field effect transistor is complementary connected to the of the second driver MOS field effect transistors Tr2. The contact hole 8 is positioned over parts of the diffusion region 5 and the gate electrode 4. A highly resistive metal layer 9 is formed on the bottom and the side walls of the contact hole 8. The highly resistive metal layer 9 has a highly resistive load R1. A second inter-layer insulator 10 is formed over the first inter-layer insulator 7 and the highly resistive metal layer 9.

FIGS. 4A through 4H are fragmentary cross sectional; elevation views illustrative of sequential steps involved in a conventional method of fabricating the conventional highly resistive static random access memory of FIG. 3.

With reference to FIG. 4A, field oxide films 2 are selectively formed on a main face of a p-type silicon substrate 1 to define an device region surrounded by the field oxide films 2.

With reference to FIG. 4B, a gate oxide film 3 is formed on the device region of the p-type silicon substrate 1. A polysilicon film 4 is formed on the gate oxide film 3 and the field oxide layers 2. The polysilicon film 4 is patterned to define a gate electrode 4. The gate electrode 4 is used as a mask for selective ion-implantation of phosphorus into the device region thereby forming an n−-type diffusion region 5b. An edge of the n−-type diffusion region 5b is defined by the edge of the polysilicon gate electrode 4.

With reference to FIG. 4C, a silicon dioxide film is entirely deposited which extends on the field oxide films 2, the gate oxide film 3 and side edge and upper surface of the polysilicon gate electrode 4. The deposited silicon dioxide film is then subjected to an anisotropic etching to leave the deposited silicon dioxide film only on side wall of the polysilicon gate electrode 4, whereby a side wall oxide film 11 is formed on the side wall of the polysilicon gate electrode 4. The side wall oxide film 11 and the photo-resist mask 12 are used as a mask for selective ion-implantation of arsenic into the n−-type diffusion region 5b except under the side wall oxide film 11 so that a heavily doped n+-type diffusion region 5a is formed and a lightly doped n−-type diffusion region 5b is defined under the side wall oxide film 11. The heavily doped n+-type diffusion region 5a and the lightly doped n−-type diffusion region 5b constitute a diffusion layer 5.

With reference to FIG. 4D, a photo-resist mask 12 is selectively formed on the field oxide film 2 and the polysilicon gate electrode 4. The side wall oxide film 11 and the gate oxide film 3 except under the polysilicon gate electrode are removed. The edge of the lightly doped n−-type diffusion region 5b is positioned in correspondence with the edge of the polysilicon gate electrode 4.

With reference to FIG. 4E, the photo-resist mask 12 is removed. A titanium film 6 is formed on the heavily doped n+-type diffusion region 5a and the lightly doped n−-type diffusion region 5b as well as on the side wall and the upper surface of the polysilicon gate electrode 4, whereby the polysilicon gate electrode 4 and the diffusion layer 5 are electrically connected to each other through the titanium film 6.

With reference to FIG. 4F, a boro-phospho silicate glass first inter-layer insulator 7 is formed which extends on the titanium film 6 and the field oxide film 2. A contact hole 8 is formed in the boro-phospho silicate glass first inter-layer insulator 7 in a predetermined region Q so that the contact hole 8 is positioned over the polysilicon gate electrode 4 over the gage oxide film 3 and the lightly doped n−-type diffusion region 5b as well as an adjacent part of the heavily doped n+-type diffusion region 5a to the lightly doped n−-type diffusion region 5b, whereby the titanium film 6 is partially shown through the contact hole 8.

With reference to FIG. 4G, a highly resistive film 9 is selectively formed on the titanium film 6 and on the side walls of the contact hole 8 of the first inter-layer insulator 7.

With reference to FIG. 4H, a boro-phospho silicate glass second inter-layer insulator 10 is formed which extends on the highly resistive film 9 and the boro-phospho silicate glass first inter-layer insulator 7.

The above conventional method, however, causes the following problems. When the side wall oxide film 11 is removed, a side wall portion of the polysilicon gate electrode 4 is also removed, whereby the edge of the polysilicon gate electrode 4 has an off-set by a distance “X” from the edge of the lightly doped n−-type diffusion region 5b. FIG. 5 is a fragmentary cross sectional elevation view illustrative of a conventional structure with an off-set region of a static random access memory. As a result, the titanium film 6 extends not only on the lightly doped n−-type diffusion region 5b, the heavily doped n+-type diffusion region 5a and the polysilicon gate electrode 4 but also on an off-set region “X” of the p-type silicon substrate 1. Since a p-n junction is formed on an interface between the n-type diffusion region 5 and the p-type silicon substrate 1, the n-type diffusion region 5 is not electrically conductive through the p-n junction interface to the p-type silicon substrate 1. However, the n-type diffusion region 5 is electrically conductive to the titanium film 6 and further the titanium film 6 is also electrically conductive to the p-type silicon substrate 1 through the off-set interface “X”, for which reason the n-type diffusion region 5 is electrically conductive through the titanium film 6 to the p-type silicon substrate 1, whereby a current may flow between the n-type diffusion region 5 and the p-type silicon substrate 1 through the titanium film 6 and the off-set interface “X”. The formation of the off-set region “X” by unintentional removal of the edge of the polysilicon gate electrode 4 together with the removal of the side wall oxide film 11 makes the static random access memory no longer operable.

In the above circumstances, it had been required to develop a novel off-set free structure of the static random access memory free from the above problems.

### SUMMARY OF THE INVENTION

Accordingly, it is an object of the present invention to provide a novel static random access memory free from the above problems.

It is a further object of the present invention to provide a novel static random access memory free of any short circuit.

It is a still further object of the present invention to provide a novel static random access memory, wherein a diffusion region is not electrically conductive to a semiconductor substrate.

It is yet a further object of the present invention to provide a novel static random access memory free of any off-set region between an edge of a gate electrode and an edge of a diffusion region.

It is a further more object of the present invention to provide a novel static random access memory reduced in a resistance between a gate electrode and a diffusion region without forming any short circuit between the diffusion region and a semiconductor substrate.

It is still more object of the present invention to provide a novel method of forming a static random access memory free from the above problems.

It is moreover object of the present invention to provide a novel method of forming a static random access memory free of any short circuit.

It is another object of the present invention to proved a novel method of forming a static random access memory, wherein a diffusion region is not electrically conductive to a semiconductor substrate.

It is still another object of the present invention to provide a novel method of forming a static random access memory free of any off-set region between an edge of a gate electrode and an edge of a diffusion region.

It is yet another object of the present invention to provide a novel method of forming a static random access memory reduced in a resistance between a gate electrode and a diffusion region without forming any short circuit between the diffusion region and a semiconductor substrate.

The present invention provides a semiconductor diffusion region structure of a first conductivity type in an upper region of a semiconductor substrate of a second conductivity type, wherein the semiconductor diffusion region structure comprises: a main portion, at least a part of which is electrically connected to an electrically conductive film structure; and an extending portion which underlies a gate insulating film underlying a gate electrode layer which is also electrically connected to the electrically conductive film structure, so that an adjacent potion of the semiconductor substrate to an edge of the extending portion of the semiconductor diffusion region structure is distanced from the electrically conductive film structure whereby the semiconductor diffusion region structure is electrically isolated from the semiconductor substrate.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIG. 1 is a circuit diagram illustrative of a conventional highly resistive static random access memory.

FIG. 2 is a fragmentary plane view illustrative of the conventional highly resistive static random access memory of FIG. 1.

FIG. 3 is a fragmentary cross sectional elevation view illustrative of the conventional highly resistive static random access memory taken along an A-A line of FIG. 2.

FIGS. 4A through 4H are fragmentary cross sectional; elevation views illustrative of sequential steps involved in a conventional method of fabricating the conventional highly resistive static random access memory of FIG. 3.

FIG. 5 is a fragmentary cross sectional elevation view illustrative of a conventional structure with an off-set region of a static random access memory.

FIG. 6 is a fragmentary cross sectional elevation view illustrative of a novel highly resistive static random access memory in a preferred embodiment in accordance with the present invention.

FIGS. 7A through 7H are fragmentary cross sectional; elevation views illustrative of sequential steps involved in a novel method of fabricating the novel highly resistive static random access memory of FIG. 6 in a preferred embodiment in accordance with the present invention.

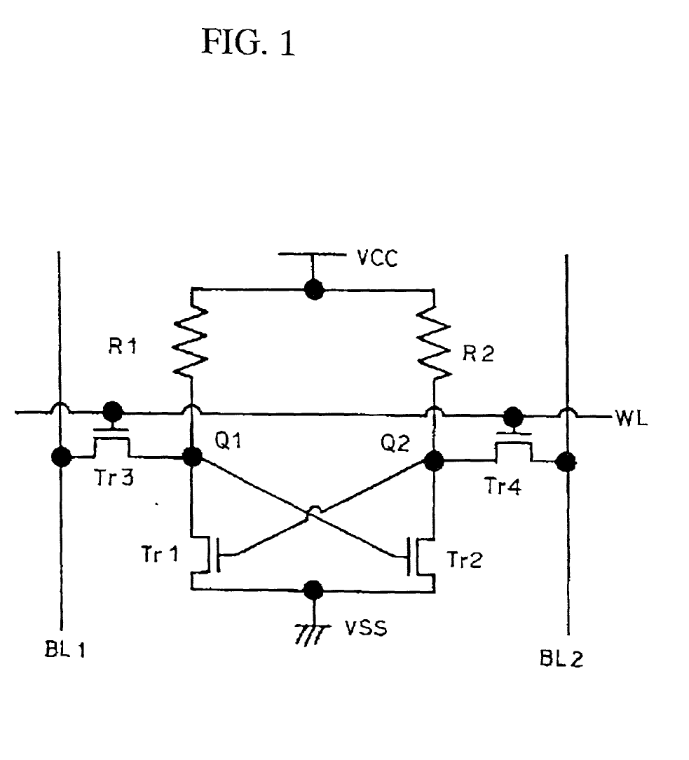

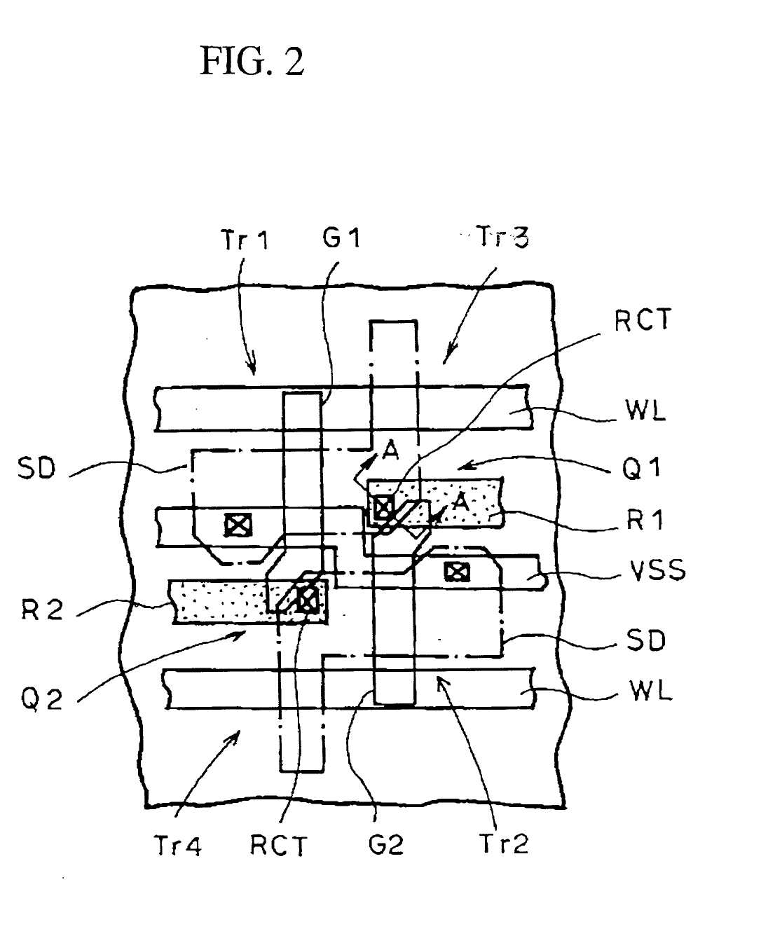

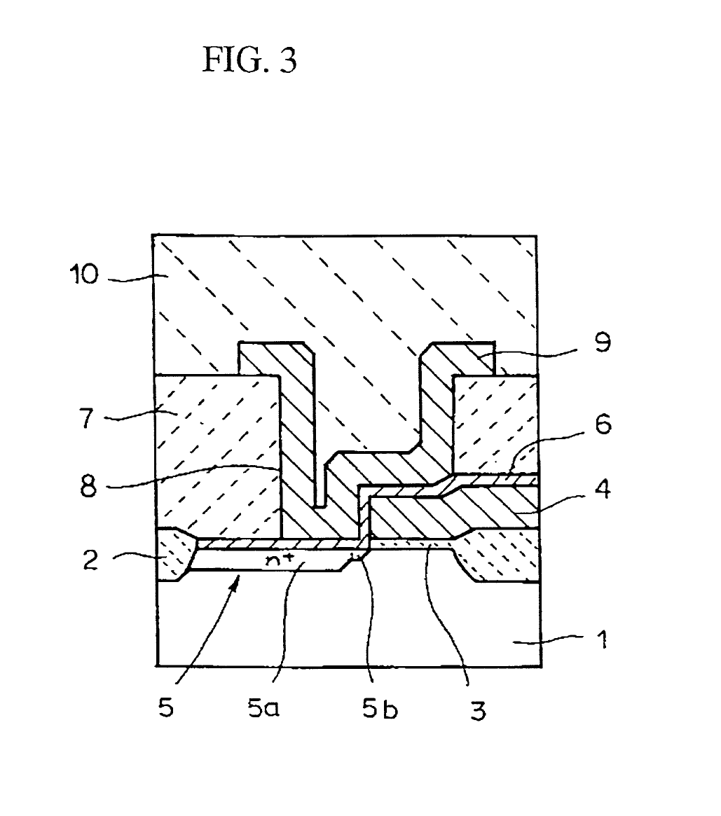

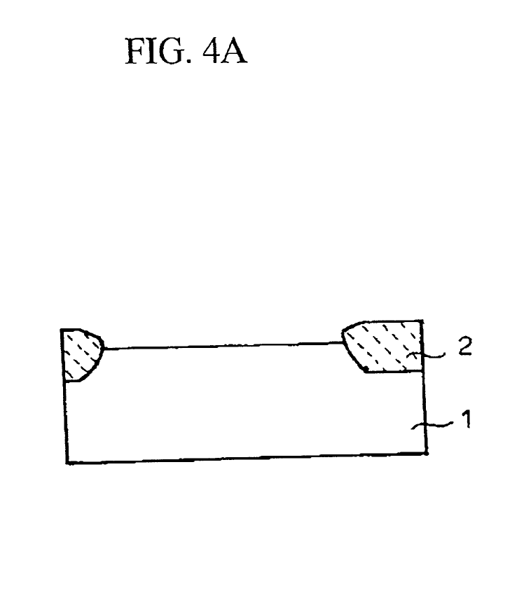

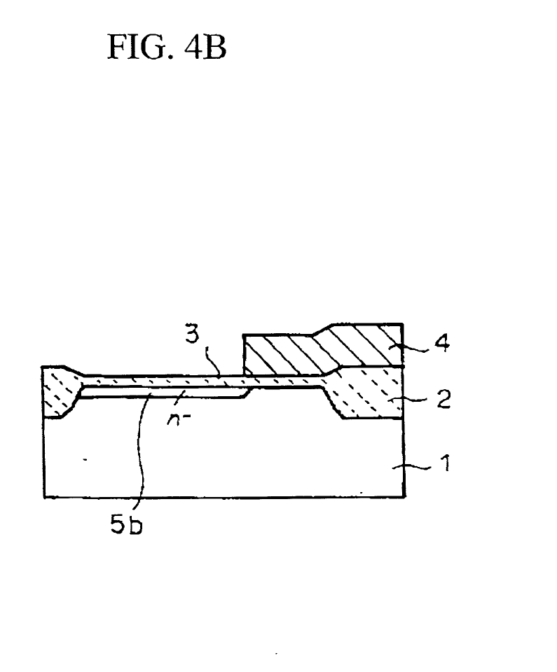

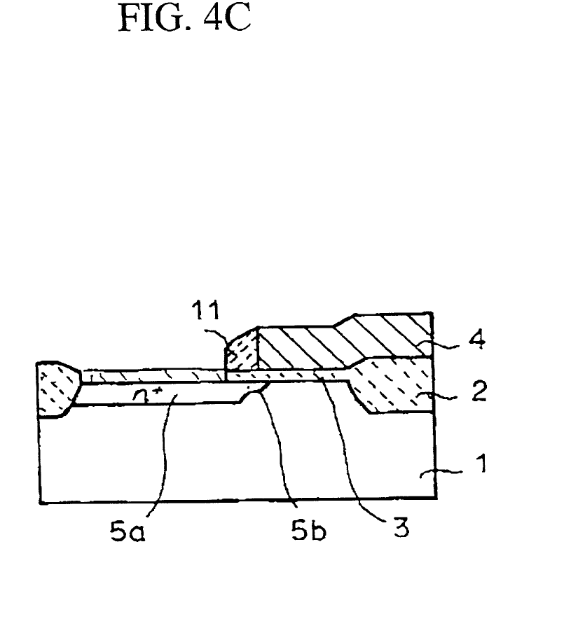

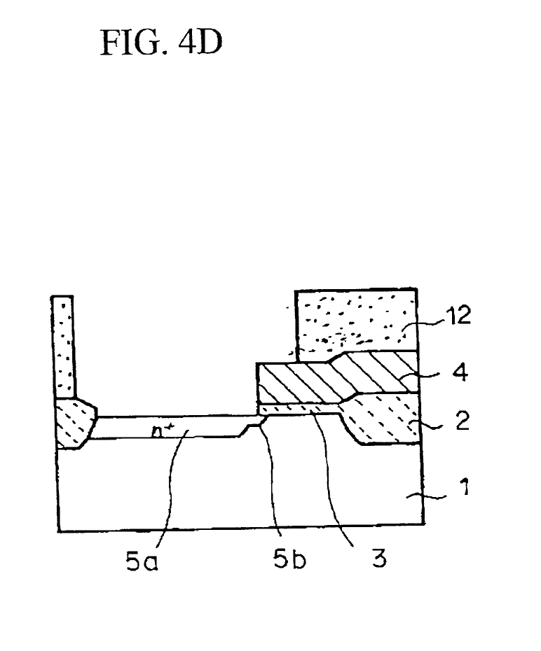

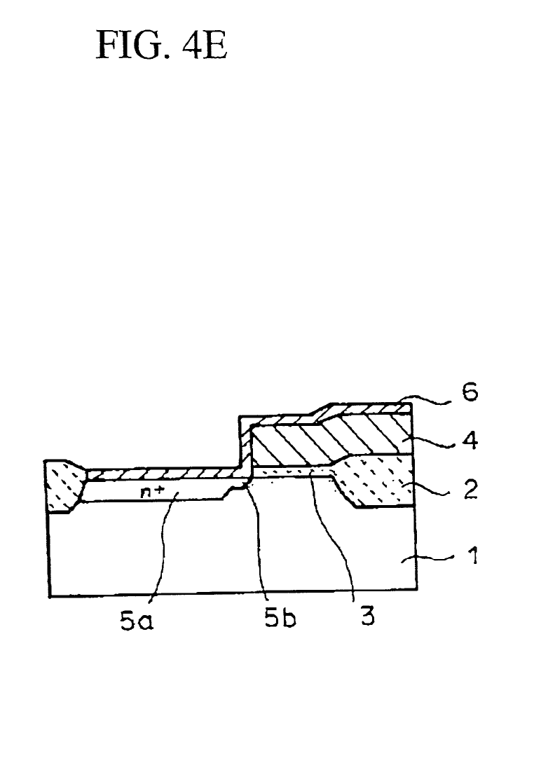

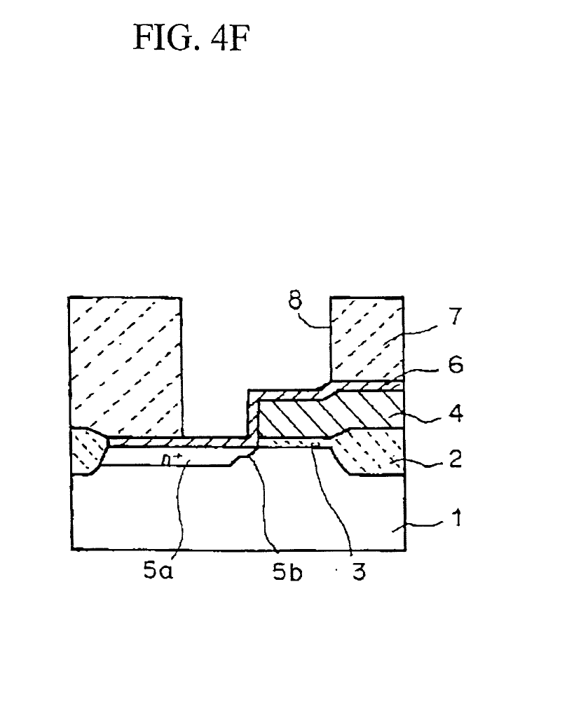

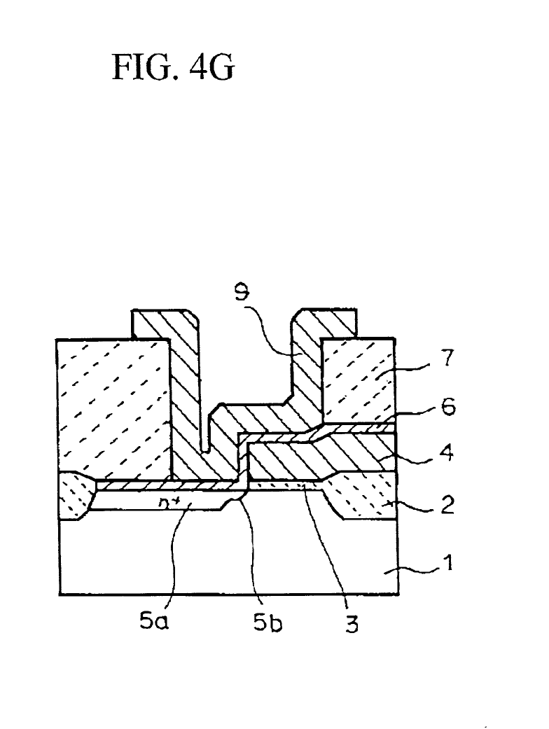

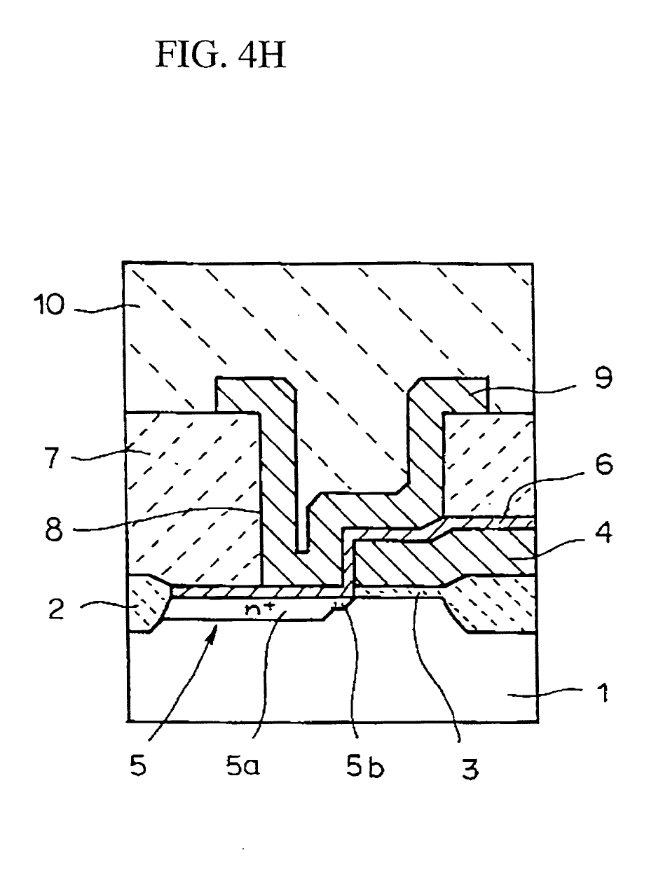

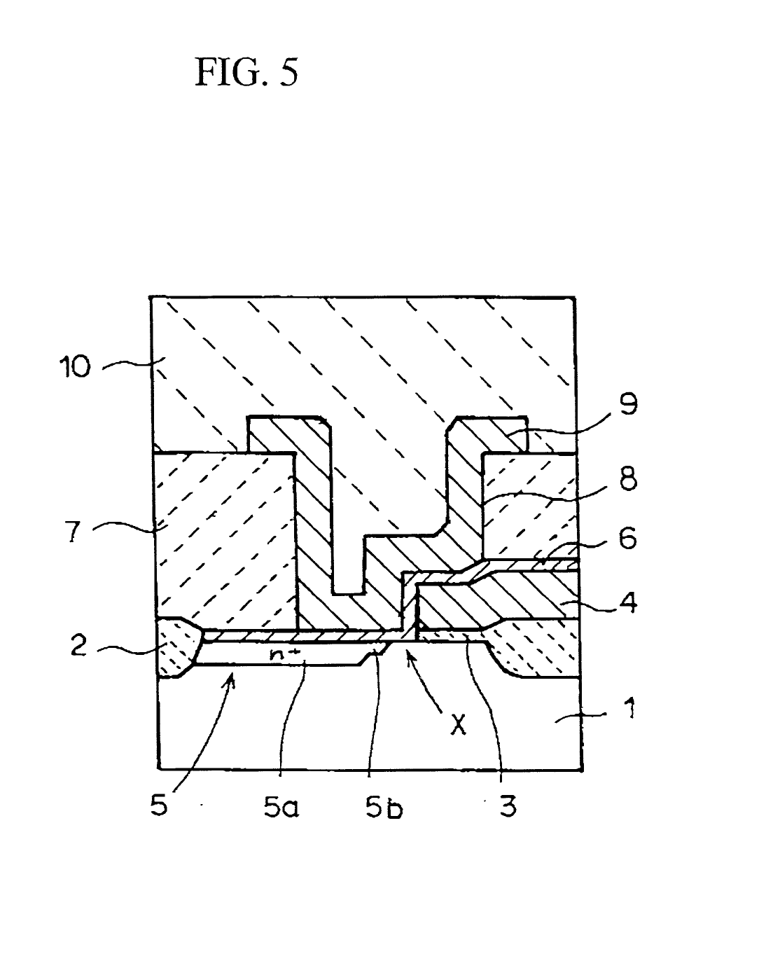

### DISCLOSURE OF THE INVENTION

The first present invention provides a semiconductor diffusion region structure of a first conductivity type in an upper region of a semiconductor substrate of a second conductivity type, wherein the semiconductor diffusion region structure comprises: a main portion, at least a part of which is electrically connected to an electrically conductive film structure; and an extending portion which underlies a gate insulating film underlying a gate electrode layer which is also electrically connected to the electrically conductive film structure, so that an adjacent potion of the semiconductor substrate to an edge of the extending portion of the semiconductor diffusion region structure is distanced from the electrically conductive film structure whereby the semiconductor diffusion region structure is electrically isolated from the semiconductor substrate.

It is preferable that the electrically conductive film structure comprises laminations of a thin metal film in contact with the main potion of the semiconductor diffusion region structure and also with the gate electrode layer and a highly resistive layer providing a highly resistive load and being in contact with the thin metal film.

It is further preferable that the highly resistive layer is provided in a contact hole in an inter-layer insulator, and the semiconductor diffusion region structure constitutes a diffusion region of a source/drain region of a field effect transistor.

The above semiconductor diffusion region structure may be applied to a static random access memory device having plural driver MOS field effect transistors and plural transfer MOS field effect transistors.

The second present invention provides a method of forming a semiconductor diffusion region structure of a first conductivity type in an upper region of a semiconductor substrate of a second conductivity type. The method comprises the steps of: carrying out an ion-implantation of a first conductivity type impurity into the semiconductor substrate at an oblique angle by use of a gate electrode layer as a mask so that a semiconductor diffusion region structure is formed which comprises a main portion uncovered by the gage electrode layer and an extending portion underlying a gate insulating film underlying the gate electrode layer; and forming an electrically conductive film structure which is in contact with at least a part of the main portion of the semiconductor diffusion region structure and also in contact with the gate electrode layer, so that an adjacent potion of the semiconductor substrate to an edge of the extending portion of the semiconductor diffusion region structure is distanced from the electrically conductive film structure whereby the semiconductor diffusion region structure is electrically isolated from the semiconductor substrate.

The third present invention provides a method of forming a semiconductor diffusion region structure of a first conductivity type in an upper region of a semiconductor substrate of a second conductivity type. The method comprises the steps of: carrying out an ion-implantation of a first conductivity type impurity into the semiconductor substrate at a vertical direction to a surface of the semiconductor substrate by use of a gate electrode layer as a mask so that a main portion of a semiconductor diffusion region structure is formed, which is uncovered by the gate electrode layer; carrying out a heat treatment to cause a thermal diffusion of an impurity to form an extending portion of the semiconductor diffusion region structure so that the extending portion underlies a gate insulating film underlying the gate electrode layer; and forming an electrically conductive film structure which is in contact with at least a part of the main portion of the semiconductor diffusion region structure and also in contact with the gate electrode layer, so that an adjacent potion of the semiconductor substrate to an edge of the extending portion of the semiconductor diffusion region structure is distanced from the electrically conductive film structure whereby the semiconductor diffusion region structure is electrically isolated from the semiconductor substrate.

### PREFERRED EMBODIMENTS

FIRST EMBODIMENT:

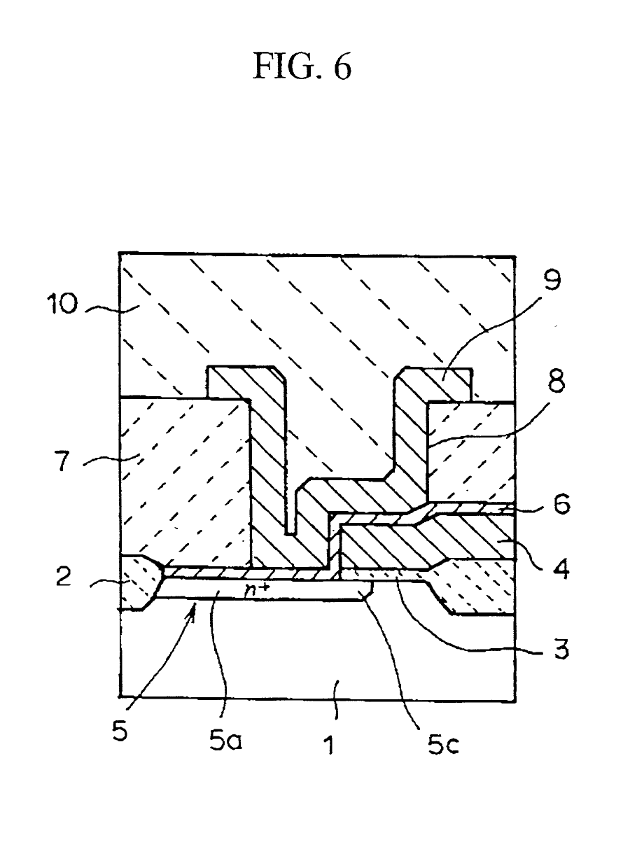

A first embodiment according to the present invention will be described in detail with reference to FIG. 6 is a fragmentary cross sectional elevation view illustrative of a novel highly resistive static random access memory. Field oxide films 2 are formed on a main face of a semiconductor substrate 1 to define an active region of the semiconductor substrate 1. A diffusion layer 5 is selectively formed on the active region of the semiconductor substrate 1. The diffusion layer 5 serves as a source or drain region of the first transfer MOS field effect transistor Tr3 and the first driver MOS field effect transistor Tr1. The diffusion layer 5 comprises and n+-type diffusion region 5a and an extending n+-type diffusion region 5c. A polysilicon gate electrode 4 is formed on a gate oxide film over a channel region and the field oxide film 2. An edge portion of the polysilicon gate electrode 4 is positioned over the extending n+-type diffusion region 5c. Namely, there is an overlapped portion between the polysilicon gate electrode 4 and the extending n+-type diffusion region 5c. A conductive film 6 of titanium is further formed which extends on the diffusion layer 5 and on the gate electrode 4. A first inter-layer insulator 7 is formed over the titanium film 6. A contact hole 8 is formed in the first inter-layer insulator 7 in the connective region Q1 through which the first transfer MOS field effect transistor is complementary connected to the of the second driver MOS filed effect transistor Tr2. The contact hole 8 is positioned over parts of the diffusion region 5 and the gate electrode 4. A highly resistive metal layer 9 is formed on the bottom and the side walls of the contact hole 8. The highly resistive metal layer 9 has a highly resistive load R1. A second inter-layer insulator 10 is formed over the first inter-layer insulator 7 and the highly resistive metal layer 9.

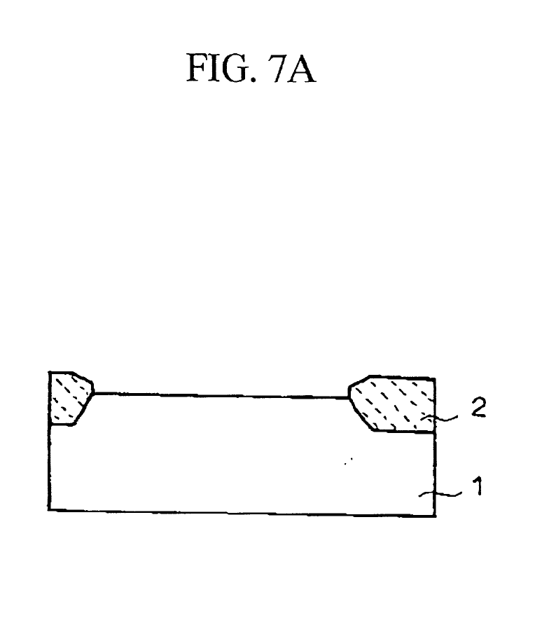

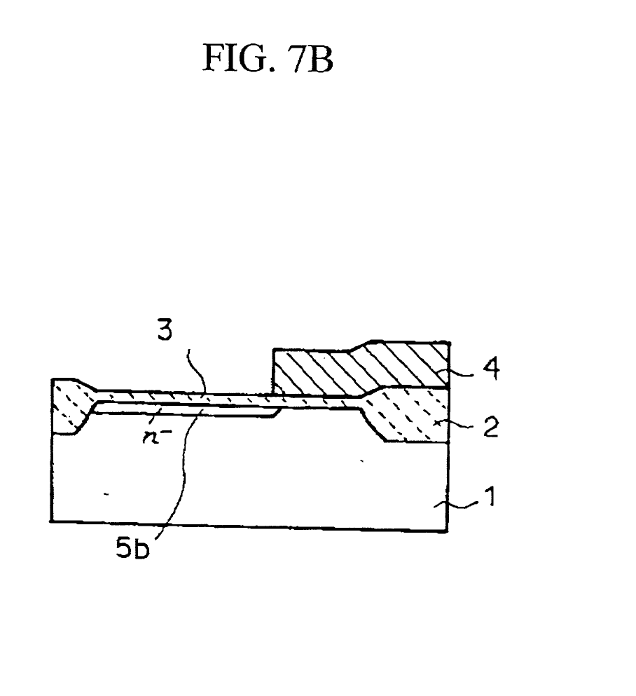

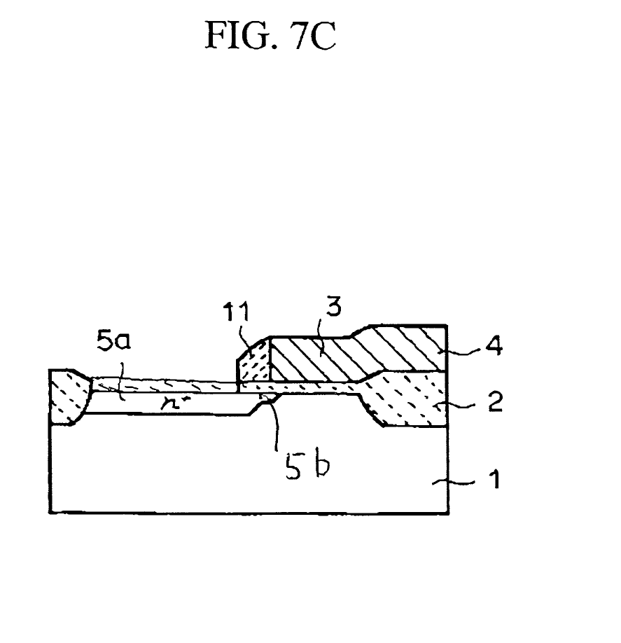

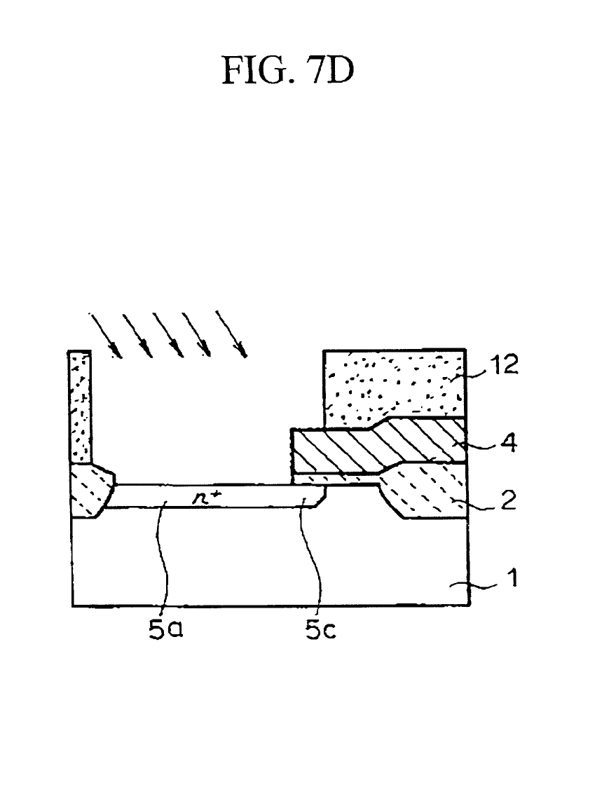

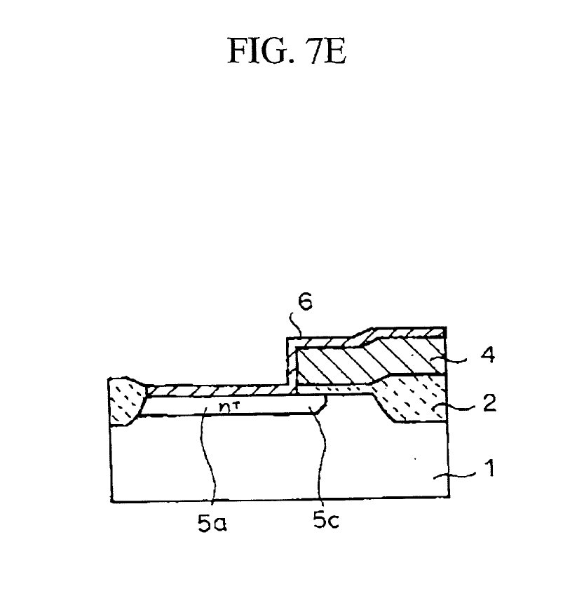

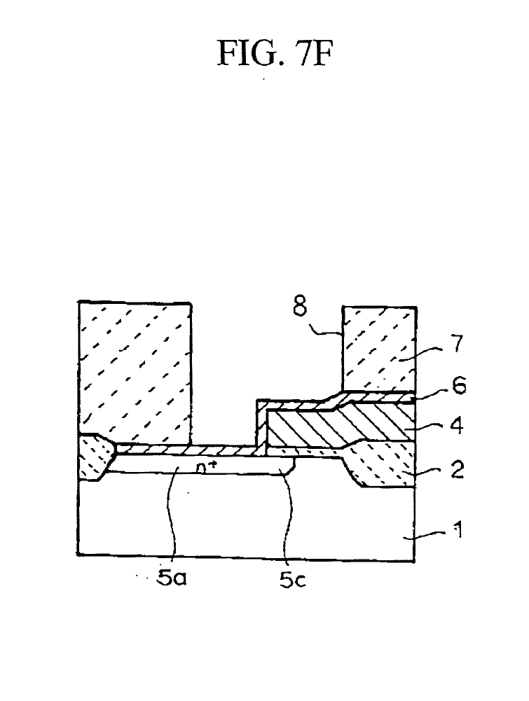

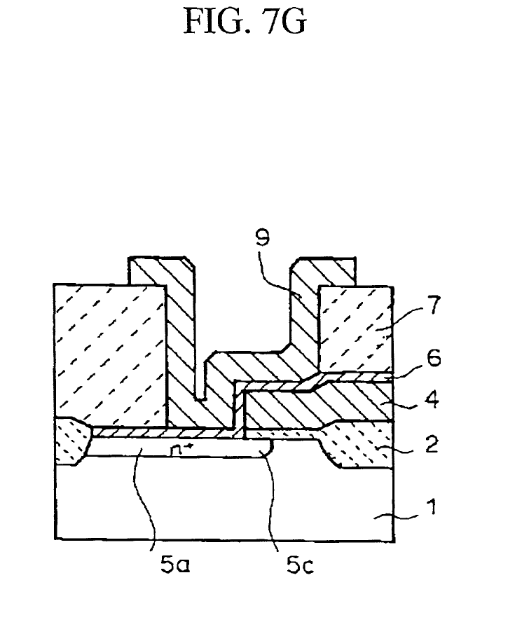

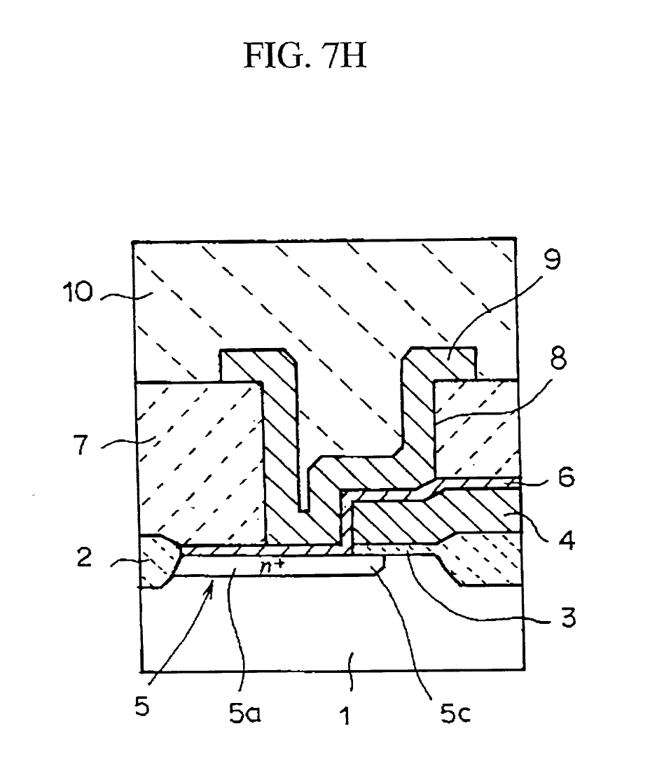

FIGS. 7A through 7H are fragmentary cross sectional elevation views illustrative of sequential steps involved in a novel method of fabricating the novel resistive static random access memory of FIG. 6.

With reference to FIG. 7A, field oxide films 2 having a thickness of 4000 angstroms are selectively formed on a main face of a p-type silicon substrate 1 to define an device region surrounded by the filed oxide films 2.

With reference to FIG. 7B, a gate oxide film 3 having a thickness of 90 angstroms is formed on the device region of the p-type silicon substrate 1. A polysilicon film 4 having a thickness of 2000 angstroms is formed on the gate oxide film 3 and the filed oxide layers 2. The polysilicon film 4 is patterned to define a polysilicon gate electrode 4. The gate electrode 4 is used as a mask for selective ion-implantation of phosphorus into the device region at an ion-implantation energy of 50 KeV at a dose of 1E13 cm⁻² thereby forming a lightly doped n−-type diffusion region 5b. An edge of the lightly doped n−-type diffusion region 5b is defined by the edge of the polysilicon gate electrode 4.

With reference to FIG. 7C, a silicon dioxide film having a thickness of 1500 angstroms is entirely deposited which extends on the field oxide films 2, the gate oxide film 3 and side edge and upper surface of the polysilicon gate electrode 4. The deposited silicon dioxide film is then subjected to an anisotropic etching to leave the deposited silicon dioxide film only on side wall of the polysilicon gate electrode 4, whereby a side wall oxide film 11 is formed on the side wall of the polysilicon gate electrode 4. The side wall oxide film 11 and the photo-resist mask 12 are used as a mask for selective ion-implantation of arsenic into the n−-type diffusion region 5b except under the side wall oxide film 11 at an ion-implantation energy of 40 keV and a dose of 4E15 cm⁻² so that a heavily doped n+-type diffusion region 5a is formed and a lightly doped n−-type diffusion region 5b is defined under the side wall oxide film 11. The heavily doped n+-type diffusion region 5a and the lightly doped n−-type diffusion region 5b is defined under the side wall oxide film 11. The heavily doped n+-type diffusion region 5a and the lightly doped n−-type diffusion region 5b constitute a diffusion layer 5.

With reference to FIG. 7D, a photo-resist mask 12 is selectively formed on the field oxide film 2 and the polysilicon gate electrode 4. The side wall oxide film 11 and the gate oxide film 3 except under the polysilicon gate electrode are removed. Concurrently, a side edge portion. of the polysilicon gate electrode 4 is also removed, whereby the edge of the polysilicon gate electrode 4 has a set-off from the edge of the lightly doped n−-type diffusion region 5b. Subsequently, an oblique ion-implantation of phosphors into the device region is carried out at an oblique angle of 30 degrees to the surface of the p-type silicon substrate 1 at an ion-implantation energy of 70 keV and a dose of 4E15 cm⁻² so that phosphorus is implanted not only into the heavily doped n+-type diffusion region 5a and the lightly doped n−-type diffusion region 5b but also into an extending part which is positioned under an end portion of the polysilicon gate electrode 4, whereby the heavily doped n+-type diffusion region 5a and a heavily doped n+-type extending diffusion region 5c are formed. A boundary between the heavily doped n+-type diffusion region 5a and the heavily doped n+-type extending diffusion region 5c is defined by the edge of the polysilicon gate electrode 4. The heavily doped n+-type extending diffusion region 5c is positioned under the end portion of the polysilicon gate electrode 4. The heavily doped n+-type diffusion region 5a and the heavily doped n+-type extending diffusion region 5c constitute a diffusion region 5. As a result, there is formed an over-lapped portion between the diffusion region 5 and the polysilicon gate electrode 4.

With reference to FIG. 7E, the photo-resist mask 12 is removed. A titanium film 6 having a thickness of 200 angstroms is formed on the heavily doped n+-type diffusion region 5a and the heavily doped n+-type extending diffusion region 5c as well as on the side wall and the upper surface of the polysilicon gate electrode 4, whereby the polysilicon gate electrode 4 and the diffusion layer 5 are electrically connected to each other through the titanium film 6.

With reference to FIG. 7F, a boro-phospho silicate glass first inter-layer insulator 7 having a thickness of 3000 angstroms is formed which extends on the titanium film 6 and the field oxide film 2. A contact hole 8 is formed in the boro-phospho silicate glass first inter-layer insulator 7 in a predetermined region Q so that the contact hole 8 is positioned over the polysilicon gate electrode 4 over the gate oxide film 3 and the lightly doped n−-type diffusion region 5b as well as an adjacent part of the heavily doped n+-type diffusion region 5a to the lightly doped n−-type diffusion region 5b, whereby the titanium film 6 is partially shown through the contact hole 8.

With reference to FIG. 7G, an SIPOS film having a thickness of 500 angstroms is entirely deposited and then patterned to form a highly resistive film 9 on the titanium film 6 and on the side walls of the contact hole 8 of the first inter-layer insulator 7.

With reference to FIG. 7H, a boro-phospho silicate glass second inter-layer insulator 10 having a thickness of 4000 angstroms is formed which extends on the highly resistive film 9 and the boro-phospho silicate glass first inter-layer insulator 7.

The above novel method makes the static random access memory free from the above problems with the conventional static random access memory. When the side wall oxide film 11 is removed, a side wall portion of the polysilicon gate electrode 4 is also removed, whereby the edge of the polysilicon gate electrode 4 has an off-set from the edge of the lightly doped n−-type diffusion region 5b. However, the oblique ion-implantation of phosphors into the device region is carried out at an oblique angle so that phosphorus is implanted not only into the heavily doped n+-type diffusion region 5a and the lightly doped n−-type diffusion region 5b but also into an extending part which is positioned under an end portion of the polysilicon gate electrode 4, whereby the heavily doped n+-type diffusion region 5a and the heavily doped n+-type extending diffusion region 5c are formed. A boundary between the heavily doped n+-type diffusion region 5a and the heavily doped n+-type extending diffusion region 5c is defined by the edge of the polysilicon gate electrode 4. The heavily doped n+-type extending diffusion region 5c is positioned under the end portion of the polysilicon gate electrode 4. The heavily doped n+-type diffusion region 5a and the heavily doped n+-type extending diffusion region 5c constitute a diffusion region 5. As a result, there is formed an over-lapped portion between the diffusion region 5 and the polysilicon gate electrode 4. As a result, the titanium film 6 extends on the heavily doped n+-type diffusion region 5a and the polysilicon gate electrode 4 but is separated or distanced by the heavily doped n+-type extending diffusion region 5c from the p-type silicon substrate 1. Since a p-n junction is formed on an interface between the n-type diffusion region 5 and the p-type silicon substrate 1, the n-type diffusion region 5 is not electrically conductive through the p-n junction interface to the p-type silicon substrate 1. Further, the n-type diffusion region 5 is electrically conductive to the titanium film 6, whilst the titanium film 6 is, however, electrically isolated from the p-type silicon substrate 1 by the heavily doped n+-type extending diffusion region 5c, for which reason the n-type diffusion region 5 is electrically isolated from the p-type silicon substrate 1, whereby no current flows between the n-type diffusion region 5 and the p-type silicon substrate 1. The formation of the overlapped portion by the intentional oblique ion-implantation following to the removal of the side wall oxide film make the static random access memory operable.

As a modification to the above angle ion-implantation, it is also possible that a vertical ion-implantation and subsequent heat treatment for impurity diffusion to form the heavily doped n+-type extending diffusion region 5c are carried out. For example, the vertical ion-implantation is carried out at the ion-implantation energy of 40 keV and a does of 7E15 cm⁻² and subsequently a heat treatment is carried out in a nitrogen atmosphere at a temperature of 850° C. for 10 minutes.

Whereas modifications of the present invention will be apparent to a person having ordinary skill in the art, to which the invention pertains, it is to be understood that embodiments as shown and described by way of illustrations are by no means intended to be considered in a limiting sense. Accordingly, it is to be intended to cover by claims all modifications which fall within the spirit and scope of the present invention.

What is claimed is:

1. A semiconductor diffusion region structure of a first conductivity type in an upper region of a semiconductor substrate of a second conductivity type,
wherein the semiconductor diffusion region structure comprises:
a main portion, at least a part of which is electrically connected to an electrically conductive film structure; and
an extending portion which underlies a gate insulating film underlying a gate electrode layer which is also electrically connected to the electrically conductive film structure,
so that an adjacent potion of the semiconductor substrate to an edge of the extending portion of the semiconductor diffusion region structure is distanced from the electrically conductive film structure whereby the semiconductor diffusion region structure is electrically isolated from the semiconductor substrate.

2. The semiconductor diffusion region structure as claimed in claim 1, wherein the electrically conductive film structure comprises laminations of a thin metal film in contact with the main potion of the semiconductor diffusion region structure and also with the gate electrode layer and a highly resistive layer providing a highly resistive load and being in contact with the thin metal film.

3. The semiconductor diffusion region structure as claimed in claim 2, wherein the highly resistive layer is provided in a contact hole in an inter-layer insulator, and the semiconductor diffusion region structure constitutes a diffusion region of a source/drain region of a field effect transistor.

4. A static random access memory device having plural driver MOS field effect transistors and plural transfer MOS field effect transistors, each having a semiconductor diffusion region structure as claimed in claim 1.

5. A method of forming a semiconductor diffusion region structure of a first conductivity type in an upper region of a semiconductor substrate of a second conductivity type, the method comprising the steps of:
carrying out an ion-implantation of a first conductivity type impurity into the semiconductor substrate at an oblique angle by use of a gate electrode layer as a mask so that a semiconductor diffusion region structure is formed which comprises a main portion uncovered by the gate electrode layer and an extending portion underlying a gate insulating film underlying the gate electrode layer; and
forming an electrically conductive film structure which is in contact with at least a part of the main portion of the semiconductor diffusion region structure and also in contact with the gate electrode layer,
so that an adjacent potion of the semiconductor substrate to an edge of the extending portion of the semiconductor diffusion region structure is distanced from the electrically conductive film structure whereby the semiconductor diffusion region structure is electrically isolated from the semiconductor substrate.

6. A method of forming a semiconductor diffusion region structure of a first conductivity type in an upper region of a semiconductor substrate of a second conductivity type, the method comprising the steps of:
carrying out an ion-implantation of a first conductivity type impurity into the semiconductor substrate at a vertical direction to a surface of the semiconductor substrate by use of a gate electrode layer as a mask so that a main portion of a semiconductor diffusion region structure is formed, which is uncovered by the gate electrode layer;
carrying out a heat treatment to cause a thermal diffusion of an impurity to form an extending portion of the semiconductor diffusion region structure so that the extending portion underlies a gate insulating film underlying the gate electrode layer; and
forming an electrically conductive film structure which is in contact with at least a part of the main portion of the semiconductor diffusion region structure and also in contact with the gate electrode layer,
so that an adjacent potion of the semiconductor substrate to an edge of the extending portion of the semiconductor diffusion region structure is distanced from the electrically conductive film structure whereby the semiconductor diffusion region structure is electrically isolated from the semiconductor substrate.
